(19) United States
(12) Patent Application Publication
(10) Pub. No.: US 2012/0113368 A1
(43) Pub. Date: May 10, 2012

(54) ARRAY SUBSTRATE, LIQUID CRYSTAL PANEL, AND MANUFACTURING METHOD THEREOF

(75) Inventor: Peilin Zhang, Beijing (CN)

(73) Assignee: BEIJING BOE OPTOELECTRONICS TECHNOLOGY CO., LTD., Beijing (CN)

(21) Appl. No.: 13/381,016

(22) PCT Filed: Apr. 6, 2011
(86) PCT No.: PCT/CN2011/072468

§ 371 Date: Dec. 27, 2011

(30) Foreign Application Priority Data
Apr. 6, 2010 (CN) 201010141582.7

(51) Int. Cl. G02F 1/1335; H01L 33/48; H01L 21/28; H01L 29/04; H01L 29/786

(52) U.S. Cl. 349/106; 257/59; 257/72; 438/587; 438/27; 257/E29.003; 257/E29.273; 257/E21.19; 257/E33.056

(57) ABSTRACT

An embodiment of the invention discloses an array substrate comprising: a base substrate; and a multilayer array pattern formed on the base substrate, wherein the multilayer array pattern comprises an internal stress layer, the internal stress layer is capable of producing internal stress which tends to make the array substrate deformed in an arched-structure convex to a side on which the array pattern is provided. In addition, another embodiment of the invention discloses a method for manufacturing the array substrate, and also a LCD comprising the array substrate and a manufacturing method therefor.

### TECHNICAL FIELD

The present invention pertains to an array substrate, a liquid crystal display (LCD) and methods for manufacturing the same.

### BACKGROUND

Thin film transistor-liquid crystal displays (TFT-LCDs) have prevailed in the flat panel display market due to characteristics such as thin profile, low power consumption, no radiation, and so on.

The main display principle of a LCD is to use an electric field to control the orientation of liquid crystal molecules and alter transmittance by means of the refractive index anisotropy of liquid crystal material to conduct display. The main structure of a LCD comprises an array substrate, a color filter substrate, polarizers, a backlight module, liquid crystal material, and so on.

In the manufacture process of a LCD, an assembling process is one of the most important processes, which is to assemble an array substrate and a color filter substrate together to form a liquid crystal cell so as to form a liquid crystal panel. In assembling, an alignment film material is first applied on each substrate and is correspondingly rubbed so that liquid crystal molecules can be aligned in a certain way on the base substrate after the assembling process; with a vacuum process, the two substrates are fixed together, and the cell gap between the two substrates are controlled with spacers.

At present, spacers can be classified into two categories: ball spacers (BS) and post spacers (post spacers). Ball spacers are sprayed onto the array substrate or the color filter substrate, and therefore there is a problem that ball spacers are distributed in great randomicity and the distribution density is difficult to control, which brings about bad effects on the display characteristics of the LCD. Thus, more LCDs employ post spacers.

Post spacers may be formed with a lithographical process in manufacturing a color filter substrate. Therefore, it is possible to precisely control the positions of post spacers in every pixel unit to improve display characteristics, such as cell gap uniformity, display contrast, and so on.

In general, a glass substrate may creep to bend mainly due to gravity or other external force, as shown in FIG. 1. The factors affecting this bend creep deformation include elasticity modulus, density, and sizes of the glass substrate, as expressed in the following formula (1):

$$l ∝ C \frac{ρ g ( 1 - {u}^{2} ) {L}^{4}}{{Et}^{2}} \qquad ( 1 )$$

wherein “l” represents a deformation amount; “C” a constant amount; “g” the gravity acceleration; “u” Poisson's ratio; “L” a length of the substrate; “p” density; “t” a thickness of the substrate; and “E” elasticity modulus.

As shown in FIG. 1, a color filter substrate 1 can creep to bend due to its own weight (gravity) during manufacturing and transferring; also, as shown in FIG. 2, an array substrate 2 can creep to bend as well. As shown in FIG. 3, in an assembling process, sealant 3 is applied onto an array substrate 2; as shown in FIG. 4, after the array substrate 2 and the color filter substrate 1 have been assembled together, the upper and lower substrates are deformed in the gravity direction due to gravity, thus the cell gap control can be realized only with post spacers in a high density, in which each sub-pixel unit is supported by a post spacers 12 to maintain the constant cell gap.

After the liquid crystal panel assembling process, the bigger is a liquid crystal limitation (an allowable deviation range of liquid crystal amount), the lower is the possibility that the liquid crystal panel is subject to a liquid crystal accumulation phenomenon under gravity because of too much liquid crystal material (liquid crystal accumulation rendering non-uniform light transmittance) and a low temperature bubble phenomenon because of too less liquid crystal. However, the liquid crystal limitation is in direct connection with the deformation of spacers under an external force; and the more deformation range the spacers have, the bigger the liquid crystal limitation is. An existing technology adopts a less spacer density to increase the deformation range of spacers.

### SUMMARY

An embodiment of the invention provides an array substrate, comprising: a base substrate; and a multilayer array pattern formed on the base substrate, wherein the multilayer array pattern comprises an internal stress layer, the internal stress layer is capable of producing internal stress which tends to make the array substrate deformed in an arched-structure convex to a side on which the array pattern is provided.

Another embodiment of the invention provides a method of manufacturing an array substrate comprising: forming a multilayer array pattern comprising an internal stress layer on a base substrate, wherein the internal stress layer can produce internal stress which tends to make the array substrate deform in an arched-structure convex to a side on which the array pattern is provided.

Further another embodiment of the invention provides a liquid crystal panel, comprising: an array substrate, a color filter substrate, and a liquid crystal layer interposed between the array substrate and the color filter substrate which have been assembled together, wherein the array substrate comprises: a base substrate; and a multilayer array pattern formed on the base substrate, wherein the multilayer array pattern comprises an internal stress layer, the internal stress layer is capable of producing internal stress which tends to make the array substrate deformed in an arched-structure convex to a side on which the array pattern is provided.

Still further another embodiment of the invention provides a method for manufacturing a liquid crystal panel, comprising: providing a color filter substrate; providing an array substrate comprising a multilayer array pattern, wherein the array pattern comprises an internal stress layer, which produces internal stress which tends to the array substrate deformed in an arched-structure convex to a side on which the array pattern is provided; and assembling the color filter substrate and the array substrate, and seal the color filter substrate and the array substrate, which has been assembled together, with sealant.

### BRIEF DESCRIPTION OF THE DRAWINGS

In order to more clearly illustrate embodiments of the present invention or that of the conventional technology, a brief introduction will be made to the accompanying drawings to be used in the description of the embodiments in the following. Obviously, the accompanying drawings of the embodiments in the following description are only a part of the embodiments of the present invention, and for those of ordinary skill in the art, other accompanying drawings may be obtained according to these accompanying drawings without inventive work.

FIG. 1 shows a structure schematic view of a color filter substrate in prior art;

FIG. 2 shows a structure schematic view of an array substrate in prior art;

FIG. 3 shows a structure schematic view of the array substrate applied with sealant in prior art;

FIG. 4 shows a structure schematic view of a liquid crystal panel formed by assembling together the array substrate and the color filter substrate assemble in prior art;

FIG. 5 shows a structure schematic view of the array substrate of an embodiment of the invention;

FIG. 6 shows a structure schematic view of the color filter substrate of an embodiment of the invention;

FIG. 7 shows a structure schematic view of the array substrate applied with sealant of the embodiment of the invention;

FIG. 8 shows a structure schematic view of the liquid crystal panel formed by assembling together the array substrate and the color filter substrate of the embodiment of the invention;

FIGS. 9-14 show the views of the process of a manufacturing method for the array substrate of the embodiment of the invention.

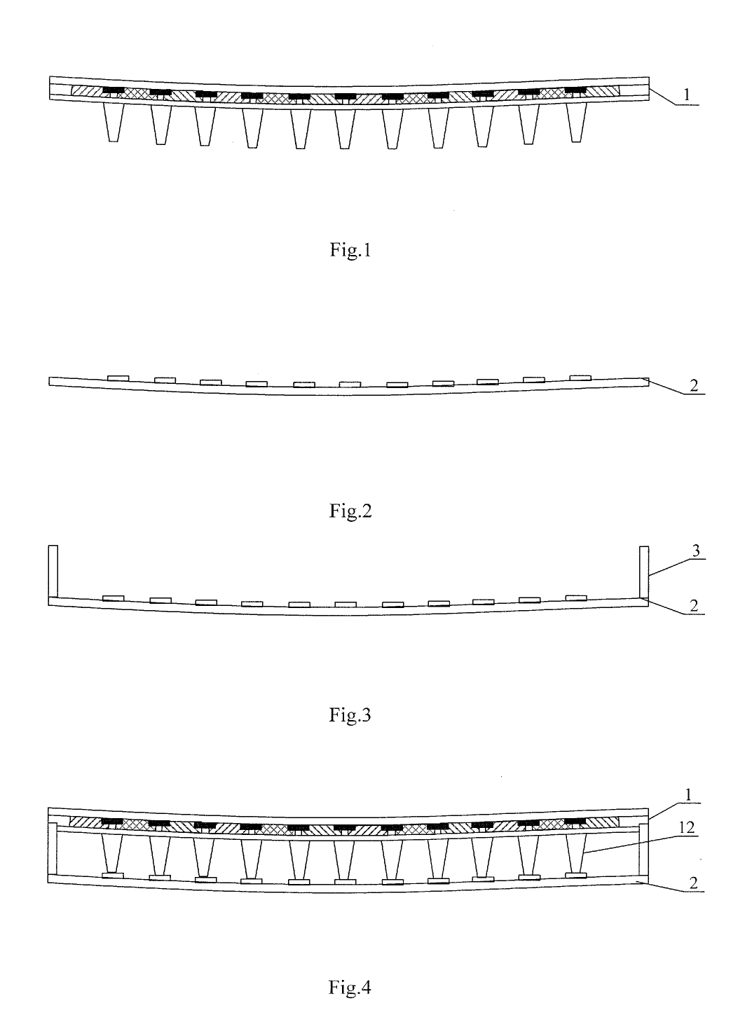

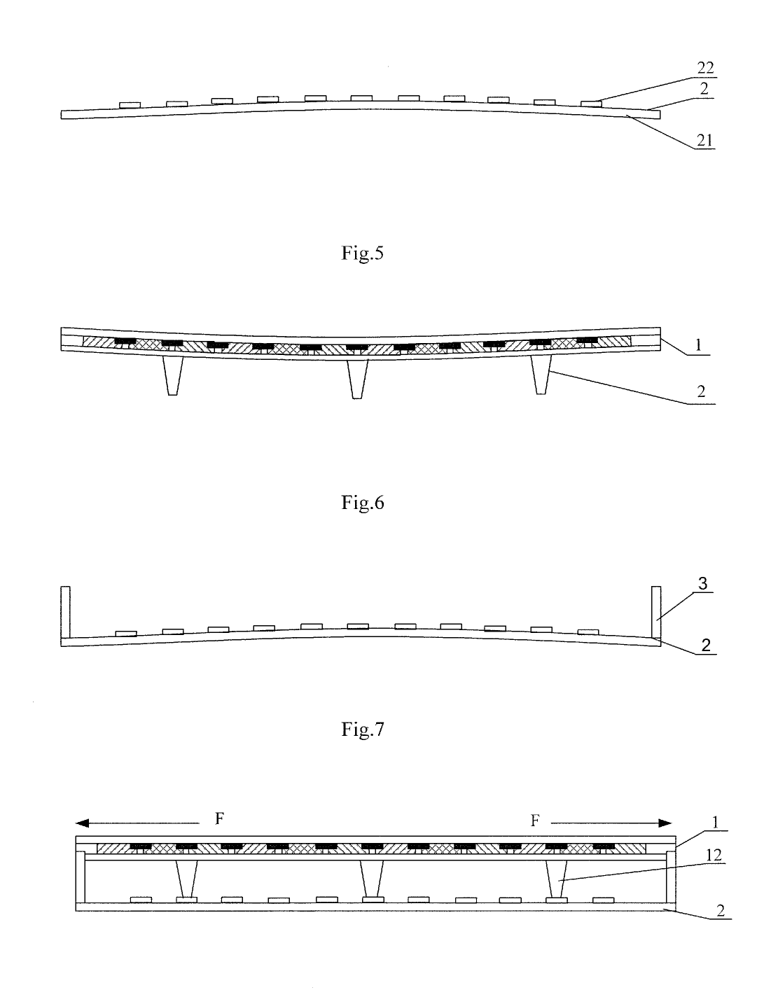

### DETAILED DESCRIPTION

The technical solutions of the embodiments of the present invention will be described clearly and completely in combination with the drawings of the embodiments of the present invention. Obviously, the described embodiments are a part of the embodiments of the present invention, but not all the embodiments. Based on the embodiments of the present invention, the other embodiments obtained by those skilled in the related art without inventive work fall within the scope of the present invention.

In the condition as shown in FIG. 4, when the liquid crystal limitation is improved by decreasing the distribution density of spacers, the inventors have found that there exist the following problems. Because in manufacturing of a liquid crystal panel, a glass substrate is subject to deformation of a certain degree (e.g., deformed in an arched-structure convex towards one side), spacers in a high density are needed to ensure the cell gap after the liquid crystal panel assembling process, and each sub-pixel unit has a corresponding spacer, which renders the deformation range of the spacers narrow. Therefore, it is not possible to improve the liquid crystal limitation by decreasing the density of the spacers and at the same time ensure a uniform cell gap after the liquid crystal panel assembling process.

Embodiments of the invention provides an array substrate, a liquid crystal panel and manufacturing methods therefor, which can counteract the deformation because of gravity or an external force after the liquid crystal panel assembling process to some degree and effectively control the cell gap uniformity.

### First Embodiment

In order to overcome the deformation because of gravity or an external force during assembling, an embodiment of the invention provides an array substrate; as shown in FIG. 5, the array substrate 2 comprises a base substrate 21 and a multiplayer array pattern 22 formed on the base substrate 21. The array pattern 22 comprises the structure layers for forming functional elements such as gate lines (gate electrodes), active layers, source and drain electrodes, data lines, and pixel electrodes and so on, and further comprises an internal stress layer, and this internal stress layer can give rise to internal stress, which makes the array substrate 2 deformed in an arched-structure convex towards one side on which the array pattern 22 is provided. On the array substrate, the gate lines and the data lines cross with each other to define a pixel unit array, and in each pixel unit, there are provided a pixel electrode for applying the voltage to drive liquid crystal material and a thin film transistor (TFT) as a switch element; the TFT comprises a gate electrode connected with a gate line, and source and drain electrodes, one of which is connected with a data line and the other is connected with a pixel electrode, and these pattern structures can be obtained by stacking layers of thin film, which are separated with an insulation layer therebetween, and patterning the stacked layers to form a multilayer pattern structure, that is, the array pattern. The internal stress layer of the first embodiment of the invention refers to a layer in which internal stress is produced. When the internal stress layer is provided on the array substrate, the internal stress layer tends to bend the array substrate towards a predetermined direction with the internal stress therein to apply a force on the array substrate.

The array pattern 22 may comprise a gate electrode layer, a gate insulation layer, an active layer, a source and drain electrode layer, a passivation layer, a pixel electrode layer and so on, which are formed on the base substrate, and may further comprise a protection layer on the above layers. The faulted TFT as a switch element may be in kinds of structure such as a bottom-gate type, a top-gate type and the like, and the invention is not limited to the structure of the switch element.

In this embodiment, a separate process can be used to form the internal stress layer, which produces internal stress therein, and tend to deform the array substrate; alternatively, a gate insulation layer, a passivation layer or a protection layer (if any), which are formed with an existing process, can be used to realize the function of the internal stress layer to produce internal stress and tend to deform the base substrate in a predetermined direction. Moreover, the resultant substrate can have more capacity to resist against the deformation in the direction apposite to the predetermined direction compared with a conventional substrate even if there is no actual bend deformation, thus can counteract the effect of gravity or an external force.

Furthermore, the gate insulation layer may comprise a high-speed gate insulation layer and a low-speed gate insulation layer; in this example, the internal stress is preferably produced in the high-speed gate insulation layer. The high-speed gate insulation layer and the low-speed gate insulation layer of the embodiment of the invention are determined according to the deposition or formation speed of the gate insulation layer, in which the gate insulation layer formed with a high-speed is referred to as the high-speed gate insulation layer while the gate insulation layer formed with a relatively low-speed is referred to as the low-speed gate insulation layer.

The embodiment of the invention alters the formation conditions for the array pattern on an array substrate, tending to render the array substrate possess an arched-structure which is convex to the side of the substrate on which the array pattern is formed (facing the side on which the color filter substrate is provided in an assembling process). With such an array substrate, in the assemble process, a horizontal internal stress effect occurs between the color filter substrate and the array substrate, offsets the deformation because of gravity or an external force to some degree, and effectively maintains the unformity of the cell gap.

### Second Embodiment

The present embodiment of the invention provides a liquid crystal panel, as shown in FIG. 5˜8, the liquid crystal panel comprises an array substrate 2, a color filter substrate 1, and a liquid crystal layer interposed between the array substrate 2 and a color filter substrate 1 after assembling. The color filter substrate 1 may bend to deform because of gravity to, for example, an arched-structure convex towards one side. The array substrate 2 comprises a base substrate 21 and a multilayer array pattern 22 formed on the base substrate 21, and the array pattern 22 comprises an internal stress layer besides the structure layers to form function elements, and this internal stress layer can give rise to internal stress tending to render the array substrate 2 deformed in an arched-structure convex towards to the side on which the array 22 pattern is provided. In assembling, the direction in which the array substrate 2 becomes convex in the arched-structure is opposite to the direction in which the color filter substrate 1 bends downward in the arched-structure due to gravity.

Furthermore, the color filter substrate 1 is provided with post spacers 12 thereon. After assembly, the spacers 12 are distributed between the array substrate 2 and a color filter substrate 1 for maintaining the space (that is, cell gap) between the array substrate 2 and color filter substrate 1.

In the technical solution of the embodiment, when the array substrate 2 are combined together with the color filter substrate, as shown in FIG. 7, sealant 3 is applied on the array substrate 2. Because the array substrate 2 are in an arched-structure, as shown in FIG. 8, these substrates 1 and 2 interact after assembly, internal stress F in the horizontal direction occurs between these substrates, which makes the color filter substrate 1 that is curved downward due to gravity return upward to the original flat condition, and as well makes the array substrate 2 in the arched shape return to the original flat condition; that is, the configuration can offset the deformation because of gravity or an external force, and the density of the post spacers 12 can be reduced, and therefore the liquid crystal limitation can be increased.

The liquid crystal panel provided in the embodiment of the invention comprises an array substrate in an arched-structure and comprising an internal stress layer, and then in the assembling process, horizontal internal stress occurs between the color filter substrate and the array substrate, which makes both the color filter substrate and the array substrate subject to deformation opposite to the original deformation and offsets to some degree the deformation due to gravity or an external force, and thus the cell gap uniformity can be maintained, at the same time the density of the post spacers can be reduced, and the liquid crystal limitation can be increased. In this embodiment, ball spacers can be employed.

In addition, the degree of the internal stress occurs in the array substrate can be controlled as desired to adjust the bend degree of the array substrate in a natural condition. Actually, when the color filter substrate and the array substrate are assembled together and the color filter substrate does not bend due to gravity, the horizontal internal stress F still occurs in the color filter substrate and the array substrate, resulting in a similar effect to the above-amended. This case is also applicable to the other embodiments of the invention.

### Third Embodiment

In order to produce horizontal internal stress between a color filter substrate and an array substrate in an assembling process, which can offset the deformation because of gravity or an external force to some degree so as to maintain the cell gap uniformity, the third embodiment of the invention provides a method for manufacturing the array substrate, and the method comprises the following steps.

Forming an array pattern comprising an internal stress layer on a base substrate, wherein the internal stress layer produces internal stress therein tending to make the array substrate deformed in an arched-structure convex to the side on which the array pattern is provided.

There are ways to form the array substrate in an arched-structure convex to the side on which the array pattern is provided. Preferably, it is possible to control the process conditions for a gate insulation layer so as to make the gate insulation layer function as the internal stress layer, forming the array substrate in the arched-structure. In a particular example, the manufacturing method for an array substrate provided in the third embodiment of the invention comprises the following steps.

Step 1001, forming the pattern of a gate electrode layer on a base substrate;

Step 1002, forming a gate insulation layer producing stress on the base substrate formed with the gate electrode layer by controlling the process conditions for the gate insulation layer (e.g., by controlling the gas flow ratio of silane and ammonia) so that the base substrate tends to deform in an arched-structure under the action of the gate insulation layer;

Step 1003, sequentially forming the patterns of an active layer, a source and drain electrode layer, a passivation layer and a pixel electrode layer on the base substrate formed with the gate insulation layer.

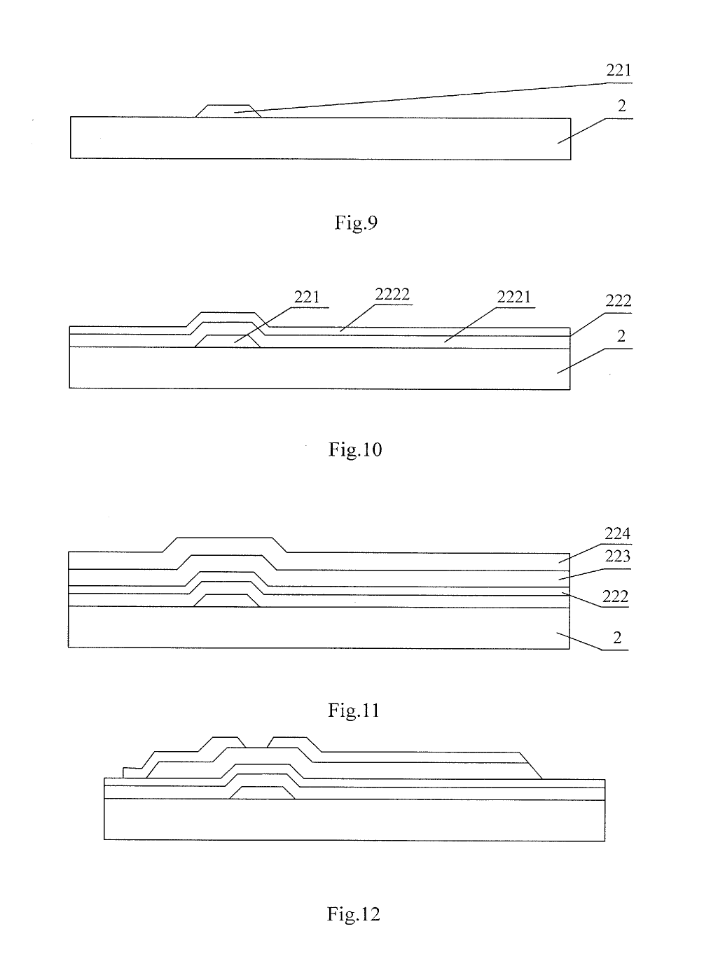

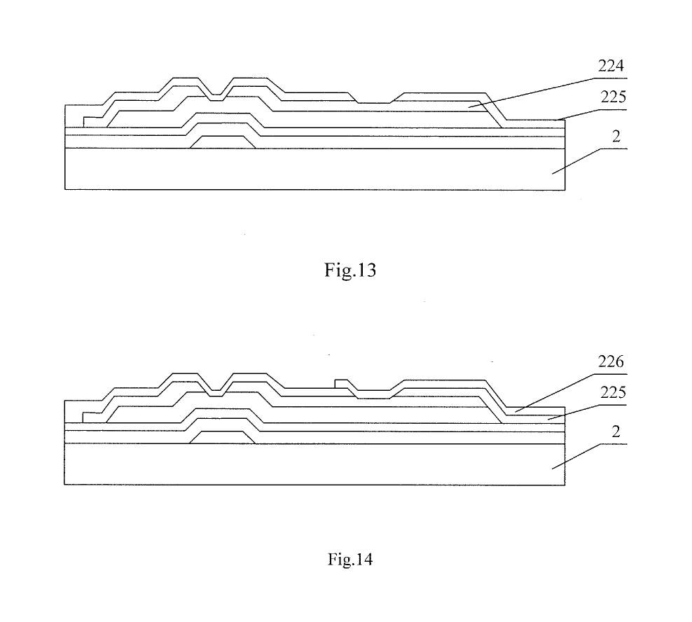

In particular, in one example, first a gate electrode layer 221 is deposited on the base substrate 2; with a patterning process including exposing, developing, etching and so on, a gate electrode pattern is formed, as shown in FIG. 9. Next, a gate insulation layer 222 is deposited on the gate electrode layer 221, and the deposition process can comprise the deposition of a high-speed gate insulation layer 2221 and the deposition of a low-speed gate insulation layer 2222 in order, as shown in FIG. 10. Particularly, the base substrate 2 is placed into a heating-furnace, the temperature inside the furnace is controlled to 330 centigrade, an electric field is applied in the furnace, the gases of SiH₄ and NH₃ are inputted at the same time to mix together as a reacting gas, and plasma is produced by glow discharge so as to form a thin film on the base substrate. The thin film formation process is conducted in two steps. First, a high-speed gate insulation layer with a thickness of about 3500 angstrom is formed by controlling the flow ratio of the mixed gases of SiH₄ and NH₃ and the deposition speed to perform a high-speed deposition. Thus formed high-speed gate insulation layer has internal stress therein, making the base substrate bend to the side on which the gate insulation film is formed and opposite to the gravity direction. In this embodiment, the gas flow ratio of the SiH₄ and NH₃ is preferably 7:30 (700:3000), and the internal stress is controlled to the level of 300 Mpa. An experiment shows that, with the above deposition process conditions, the array substrate can be formed in an arched-structure convex upward, and in the subsequent assembling process, horizontal internal stress can be produced between the color filter substrate and the array substrate, more effectively offset the deformation because of gravity or an external force, make both the array substrate and the color filter substrate to be flat after assembled, and thus ensure the cell gap uniformity. In this example, the function of the internal stress layer is realized by the high-speed gate insulation layer; at the same time, an interface layer (low-speed gate insulation layer) is further deposited on the formed high-speed gate insulation layer so as to ensure the characteristics of TFT. Also, the low-speed gate insulation layer is formed with a thickness of about 500 angstroms by controlling the gas flow ratio of SiH₄ and NH₃ and the deposition speed. This interface layer can have a good uniformity because of the slow deposition and good ion mobility when contracting with the active layer in the TFT channel (if only the low-speed deposition is performed, a better effect can be obtained, but in terms of production efficiency, the method including a high-speed and low-speed deposition processes is employed). In a gate insulation layer etching process, the portion of low-speed gate insulation layer only in the TFT channel is left but the portions of the low-speed gate insulation layer in other regions are etched away. Further, an active layer 223 is deposited on the base substrate 2 formed with the gate insulation layer 222. Then, a source and drain electrode layer 224 is deposited on the base substrate formed with the active layer 223, as shown in FIG. 11, and further the patterns of the layers are formed with patterning processes on the layers, including exposing, developing, etching and so on, as shown in FIG. 12. Next, a passivation layer 225 is deposited on the base substrate formed with the source and drain electrode layer 224 and patterned by exposing, developing, etching and so on, as shown in FIG. 13. Next, a pixel electrode layer 226 is deposited on the base substrate formed with the passivation layer 225 and patterned by exposing, developing, etching and so on to form the pixel electrode pattern, as shown in FIG. 14.

In the technical solution of the embodiment of the invention, the internal stress layer is not formed with a separate process but realized by modifying the formation process of the array substrate by controlling the process conditions for the gate insulation layer and adjusting the gas flow ratio of silane and ammonia or other process conditions so as to form a gate insulation layer producing internal stress therein, which tends to make the array substrate deformed to some degree in an arched-structure convex upward to the side on which the gate insulation layer is formed. Therefore, in the subsequent assembling process, horizontal internal stress is produced between the color filter substrate and the array substrate, offsets to some degree the deformation because of gravity or an external force, and maintains the cell gap uniformity.

In the above description, the TFT of a bottom-gate type is taken for example, but the TFT of a top-gate type can be formed on the array substrate as a switch element. In formation of the top-gate type TFT, the gate insulation layer can also be formed as the internal stress layer to obtain the array substrate according to the embodiment of the invention.

### Fourth Embodiment

The fourth embodiment are substantially similar to the manufacturing method for an array substrate provided in the third embodiment, and the difference lies in that, the function of the internal stress layer is realized with a passivation layer, that is, by modifying the process to form the passivation layer, the passivation layer is obtained which has internal stress, so that the array substrate deform to be in an arched-structure under the action of the passivation layer. In particular, the manufacturing method for an array substrate provided in the fourth embodiment of the invention comprises the following steps.

Step 2001, forming the patterns of a gate electrode layer, a gate insulation layer, an active layer and a source and drain electrode layer on the base substrate;

Step 2002, forming a passivation layer, which has internal stress therein, on the base substrate formed with the source and drain electrode layer by adjusting the gas flow ratio of silane and ammonia, so that the base substrate is deformed to be in an arched-structure under the action of the passivation layer;

Step 2003, forming a pixel electrode layer on the base substrate formed with the passivation layer.

In particular, in one example, first a gate electrode layer 221 is deposited on the base substrate 2; with a patterning process including exposing, developing, etching and so on, a gate electrode pattern is formed, as shown in FIG. 9. Next, a gate insulation layer 222 is deposited on the gate electrode layer 221, and the deposition process can comprise the deposition of a high-speed gate insulation layer 2221 and the deposition of a low-speed gate insulation layer 2222 in order, as shown in FIG. 10. Subsequently, an active layer 223 is deposited on the base substrate deposited with the gate insulation layer 222. Then, a source and drain electrode layer 224 is deposited on the base substrate formed with the active layer, as shown in FIG. 11; further the above layers are patterned with a patterning process including exposing, developing, etching and so on to form the patterns of the stacked layers, as shown in FIG. 12. Next, a passivation layer 225 is deposited on the base substrate formed with the source and drain electrode layer 224 and then patterned by a patterning process including exposing, developing, etching and so on, as shown in FIG. 13. The base substrate 2 is placed into a heating-furnace, the temperature inside the furnace is controlled to 330 centigrade, an electric field is applied in the furnace, the gases of SiH₄ and NH₃ are inputted at the same time to mix together as a reacting gas, and plasma is produced by glow discharge so as to form a thin film on the base substrate. In this step, by controlling the process conditions for the passivation layer 225, that is, adjusting the process conditions such as the gas flow ratio of SiH₄ and NH₃ and so on, internal stress is produced in the passivation layer 225 and makes the base substrate bend to the side on which the passivation layer 225 is formed. In this embodiment, the gas flow ratio of the SiH₄ and NH₃ is preferably 7:30 (700:3000), and the internal stress of 300 Mpa can be produced, making the base substrate bend to the side, on which the passivation layer 225 is formed, in an arched-structure. Different from the previous embodiment in which the gate insulation layer functions as the internal stress layer, because the passivation layer 225 needs only one step of patterning process to be formed, the process become easier for the passivation layer 225 to realize the function of the internal stress layer. Next, a pixel electrode layer 226 is deposited on the base substrate formed with the passivation layer 225 and patterned by a patterning process including exposing, developing, etching and so on to form the pattern of the pixel electrode, as shown in FIG. 14.

In the technical solution of the embodiment of the invention, the internal stress layer is not formed with a separate process but the function of the internal stress layer is realized with the passivation layer by modifying the formation process of the array substrate; by controlling the process conditions for the gate insulation layer, for example, adjusting the gas flow ratio of silane and ammonia or other process conditions, a passivation layer produces internal stress therein, which tends to make the array substrate deformed to some degree in an arched-structure convex upward to the side on which the passivation layer is formed. Therefore, in the subsequent assembling process, horizontal internal stress is produced between the color filter substrate and the array substrate, offsets to some degree the deformation because of gravity or an external force, and maintains the cell gap uniformity. Different from the previous embodiment in which the gate insulation layer functions as the internal stress layer, because the passivation layer needs only one step of patterning process to be formed, the process become easier for the passivation layer to realize the function of the internal stress layer.

In the above description, the TFT of a bottom-gate type is taken for example, but the TFT of a top-gate type can be formed on the array substrate as a switch element. In formation of the top-gate type TFT, the gate insulation layer can also be formed as the internal stress layer to obtain the array substrate according to the embodiment of the invention.

### Fifth Embodiment

The manufacturing method for an array substrate provided in the fifth embodiment of the invention comprises the following steps.

Step 3001, forming a color filter substrate. The color filter substrate may bend under the action of gravity.

Step 3002, forming an array substrate which tends to deform to be convex towards the side on which an array pattern is provided.

The method for manufacturing the array substrate can be the same as that described in the third embodiment or the fourth embodiment, thus the detailed description is omitted here.

Step 3003, assembling together the color filter substrate and the array substrate, and sealing the assembled color filter substrate and array substrate with sealant, with internal stress being produced between the array substrate and the color filter substrate, thus forming a liquid crystal panel.

Because the array substrate in an arched-structure that is formed in the Step 3002 is used in assembling by placing the color filter substrate onto the array substrate, spacers of a less density are formed in the manufacturing of the color filter substrate to overcome the deformation of the substrate, due to gravity or other force, after the assembly. The internal stress between the array substrate in an arched-structure and the color filter substrate can supplement any insufficiency to maintain the cell gap uniformity.

When the color filter substrate and the array substrate, which have been assembled together, are sealed with sealant, the two substrates interact with each other, which produces horizontal internal stress between these substrates; the internal stress F makes the color filter substrate 1 that is curved downward due to gravity return upward to the original flat condition, and as well makes the array substrate in the arched shape return to the original flat condition. Thus, the configuration can offset the deformation because of gravity or an external force, and the density of the post spacers can be reduced, and therefore the liquid crystal limitation can be increased.

The embodiments of the invention can produce internal stress therein by modifying the process conditions of the array substrate, and controlling the process conditions for forming the array substrate pattern, e.g., adjusting the gas flow ratio of silane and ammonia or other process conditions, and the internal stress tends to make the array substrate deformed to some degree in an arched-structure (e.g., to the side on which the array pattern is provided), and spacers can be designed again to reduce density and distribution. However, even if the array substrate does not deform actually, the cases are still in the scope of the invention. In the assembly process, horizontal internal stress occurs between the color filter substrate and the array substrate, offsets to some degree the deformation because of gravity or an external force, and maintains the cell gap uniformity. Furthermore, because the density of the spacers are reduced, the liquid crystal limitation can be increased, the possibility is lowered that the liquid crystal panel is subject to a liquid crystal accumulation phenomenon under gravity because of too much liquid crystal material and a low temperature bubble phenomenon because of too less liquid crystal.

The above description are only the embodiments of the invention, but the scope of the invention is not limited thereto, and those skilled in the art easily can make modification and substitution with the teaching of the invention, such modification and substitution should fall within the scope of the invention. Therefore, the scope of the invention is determined with the following claims.

What is claimed is:

1. An array substrate, comprising:
a base substrate; and
a multilayer array pattern formed on the base substrate,
wherein the multilayer array pattern comprises an internal stress layer, the internal stress layer is capable of producing internal stress which tends to make the array substrate deformed in an arched-structure convex to a side on which the array pattern is provided.

2. The array substrate according to claim 1, wherein the internal stress layer is a gate insulation layer in the multilayer array pattern.

3. The array substrate according to claim 2, wherein the gate insulation layer comprises a high-speed gate insulation layer and a low-speed gate insulation layer that are stacked together, and the high-speed gate insulation layer produces the internal stress.

4. The array substrate according to claim 1, wherein the internal stress layer is a passivation layer in the multilayer array pattern.

5. A method of manufacturing an array substrate, comprising:
forming a multilayer array pattern comprising an internal stress layer on a base substrate, wherein the internal stress layer can produce internal stress which tends to make the array substrate deform in an arched-structure convex to a side on which the array pattern is provided.

6. The method according to claim 5, wherein the internal stress layer is a gate insulation layer in the multilayer array pattern.

7. The method according to claim 5, wherein a gas flow ratio of silane and ammonia is controlled in forming the gate insulation layer so that the internal stress can be produced in the gate insulation layer.

8. The method according to claim 5, wherein the gate insulation layer comprises a high-speed gate insulation layer and a low-speed gate insulation layer that are stacked together, and the high-speed gate insulation layer produces the internal stress.

9. The method according to claim 5, wherein a gas flow ratio of silane and ammonia is controlled in forming the high-speed gate insulation layer so that the internal stress can be produced in the high-speed gate insulation layer.

10. The method according to claim 5, wherein the internal stress layer a passivation layer in the multilayer array pattern, and a pixel electrode layer is formed on the base substrate on which the passivation layer has been formed.

11. The method according to claim 10, wherein a gas flow ratio of silane and ammonia is controlled in forming the passivation layer so that the internal stress can be produced in the passivation layer.

12. A liquid crystal panel, comprising:
an array substrate,
a color filter substrate, and
a liquid crystal layer interposed between the array substrate and the color filter substrate which have been assembled together,
wherein the array substrate comprises:
a base substrate; and
a multilayer array pattern formed on the base substrate,
wherein the multilayer array pattern comprises an internal stress layer, the internal stress layer is capable of producing internal stress which tends to make the array substrate deformed in an arched-structure convex to a side on which the array pattern is provided.

13. The liquid crystal panel according to claim 12, further comprising spacers distributed between the array substrate and the color filter substrate, wherein the spacers are adapted to maintain a gap between the array substrate and the color filter substrate.

14. A method for manufacturing a liquid crystal panel, comprising:
providing a color filter substrate;
providing an array substrate comprising a multilayer array pattern, wherein the array pattern comprises an internal stress layer, which produces internal stress which tends to the array substrate deformed in an arched-structure convex to a side on which the array pattern is provided; and
assembling the color filter substrate and the array substrate, and seal the color filter substrate and the array substrate, which has been assembled together, with sealant.

15. The method according to claim 14, wherein spacers are distributed between the array substrate and the color filter substrate and are adapted to maintain a gap between the array substrate and the color filter substrate.
